(19) United States
(12) Patent Application Publication
(10) Pub. No.: US 2003/0156388 A1
(43) Pub. Date: Aug. 21, 2003

(54) Electrical device comprising a housing

(76) Inventors: Leif Christensen, Aalborg (DK); Henry Lechner, Peine (DE)

Correspondence Address: BELL, BOYD & LLOYD, LLC, P. O. BOX 1135, CHICAGO, IL, 60690-1135, US

(21) Appl. No.: 10/169,455

(22) PCT Filed: Dec. 28, 2000
(86) PCT No.: PCT/DE00/04664

(30) Foreign Application Priority Data
Dec. 31, 1999 (DE) 199-63-975.2

(51) Int. Cl. H05K 7/00

(52) U.S. Cl. 361/729

(57) ABSTRACT

The invention relates to an electrical device (1) comprising a housing (10), Said electrical device (1) has fixing elements (12) for detachably fixing a card (20) to the housing (10). The fixing elements (12) are bracket-shaped and are positioned in such a way that said fixing elements (12) can be elastically deflected from an inoperative position. The fixing elements (12) are deflected at least temporarily from the inoperative position to fix the card (20) to the housing (10).

### PRIOR ART

Radio telephones, in particular mobile telephones, are known in which a SIM card is fitted to the housing of the radio telephone to identify a user. In order to fix such a card to the housing of radio telephones, as a rule securing components are used, in order that the card cannot inadvertently be lost.

### ADVANTAGES OF THE INVENTION

By comparison, the electrical appliance according to the invention, having the features of the main claim, has the advantage that no additional component is used and that, by means of simple insertion and latching of the card in the housing and to the housing, secure fixing of the same is possible.

Furthermore, it is advantageous that the electrical device comprises a stop for fixing the card, the stop interacting with the fixing means and the card in such a way that during the fixing of the card by the fixing means, the action of a force absorbed by the stop is exerted at least temporarily on the card.

In this way, the card can be fixed particularly easily to the electrical device, since the card is held and guided by the fixing means and to the stop even during the operation of fixing the card.

In addition, it is advantageous that the fixing means and the stop are connected in one piece at least to part of the housing. This makes it simply possible to fix the card securely to the housing without additional components.

Furthermore, it is advantageous that the fixing means comprises a first securing face and that the stop comprises a second securing face, the securing faces fixing the card to the housing. This makes particularly simple and secure fitting of the card to the electrical device possible.

Furthermore, it is advantageous that the fixing means can be deflected from the inactive position when the card is fixed to the housing. In this case, the deflection results in a restoring force of the fixing means, as a result of which an additional securing function against detachment of the card from the electrical device is effected.

Furthermore, it is advantageous that during the detachment of the fixing of the card, the fixing means are deflected at least temporarily from their position with the card fixed to the housing. In this way, in order to detach the card counter to the restoring force of the fixing means, work has to be done, so that detachment of the fixing of the card from the housing of the electrical device can only be done deliberately.

Furthermore, it is advantageous that in the region of the stop, means for detaching the card are provided, the means for detaching the card being suitable, as a result of displacement of the card, to effect a deflection of fixing means and cancelation of the fixing of the card with respect to the second securing face. This means that the card can be detached from the electrical device with simple means and in particular without tools.

Furthermore, it is advantageous that the detachment means are provided in the form of a recess in the region of the stop. As a result, even removal of the card from the electrical device by means of a single finger is possible.

Furthermore, it is advantageous that the card is an identification card, in particular a SIM card. As a result, an identification card can be fitted easily and securely to the electrical device. Such a card can also be detached easily, so that a user, whose identity the card represents, can use a plurality of electrical devices, by fixing the card firstly to a first electrical device and then to a second electrical device.

### DRAWING

An exemplary embodiment of the invention is illustrated in the drawing and explained in more detail in the following description. In the drawing

FIG. 1 shows a perspective illustration, primarily of the rear of an electrical device comprising a housing,

FIG. 2 shows a view of the rear of the electrical device with a section line SIM-SIM,

FIG. 3 shows a sectional illustration of the electrical device along the section line SIM-SIM and

FIG. 4 shows an enlarged illustration of a detail of the sectional illustration along the section line SIM-SIM.

### DESCRIPTION OF THE EXEMPLARY EMBODIMENT

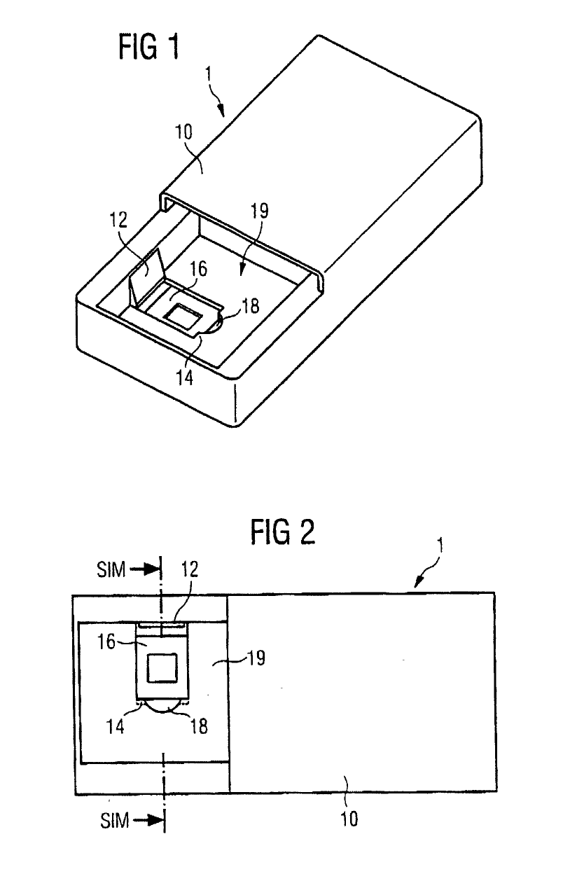

FIG. 1 shows a perspective illustration of an electrical device 1 comprising a housing 10. The electrical device 1 is in particular designed to be portable, but can also be operated in a stationary manner. Furthermore, the electrical device 1 is designed in particular as a radio telephone, for example as a mobile radio telephone, cordless telephone or the like. FIG. 1 shows substantially the rear of the electrical appliance 1, where in the exemplary embodiment fixing means 12 for fixing a card 20 (not illustrated in FIG. 1), a stop 14, a card holder 16 and means for detaching 18 the card 20 are provided. The fixing means 12, the stop 14, the holder 16 and the detachment means 18 in the exemplary embodiment are fitted in particular in the area of a battery or rechargeable battery shaft 19, for example at the bottom of a battery or rechargeable battery shaft 19.

In FIG. 2, all the elements known from FIG. 1 and belonging to the electrical device 1 are illustrated in a plan view, a section line SIM-SIM also being shown in FIG. 2.

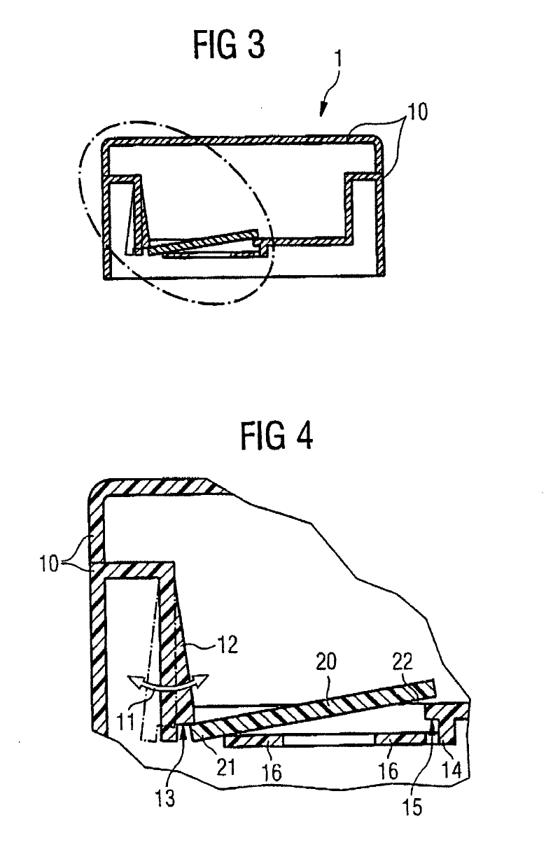

FIG. 3 represents a sectional illustration along the section line SIM-SIM of the electrical device 1. Because of the size of the illustration, only the housing 10 of the electrical device 1 is designated in FIG. 3, but the part of the sectional illustration that is essential to the invention being designated in more detail by being circled and illustrated on an enlarged scale in FIG. 4.

The enlarged illustration shown in FIG. 4 of a subarea of the sectional illustration along the section line SIM-SIM of the electrical device 1 comprises the housing 10, in a way analogous to the preceding figures, and furthermore illustrates the fixing means 12 which, in the exemplary embodiment, are connected to the housing 10 in one piece and project in the manner of a bracket into the interior of the housing 10. In the exemplary embodiment, the fixing means 12 are shaped in such a way that a first leg of the fixing means 12, not specifically designated, projects into the interior of the housing 10, a second leg of the fixing means 12, likewise not specifically designated, adjoining the first leg, its end facing away from the first leg projecting freely into the interior of the housing 10 and in the following text also being designated the free end of the second leg of the fixing means 12. The second leg is arranged approximately at right angles with respect to the first leg of the fixing means 12 and is considerably longer than the first leg of the fixing means 12. For the second leg of the fixing means 12, the result is therefore that in the region of the fixing means 12, it runs substantially parallel to the wall of the housing 10. In this way, the action of a force on the free end of the fixing means 12 leads to elastic deformation of the fixing means 12 and therefore to deflection, in particular of the second leg of the fixing means 12, in such a way that the free end of the fixing means 12 is more or less removed from the wall of the housing 10 in the region of the fixing means 12, depending on the deflection. In the absence of a force at their free end, the bracket-shaped fixing means 12 assume an inactive position, the possible deflections of the fixing means 12 being illustrated in FIG. 4 by an arrow 11.

At their free end, the fixing means 12 have a recess, not specifically designated, so that a first securing face 13 is produced at right angles to the course of the second leg. In the exemplary embodiment, the recess is made, for example, in such a way that the cross section of the second leg, beginning from its connection to the first leg, becomes larger toward its free end, the cross section of the second leg of the fixing means 12 being reduced abruptly, shortly before its free end, to that of the wall of the housing 10 and in this way permitting the first securing face 13 to be produced.

FIG. 4 also shows the holder 16, on which the card 20 rests in the installed state of the card. The holder 16 comprises in particular electric contacts, not illustrated, which can be connected to further electric contacts which are located on the card 20 and not illustrated.

Also shown in FIG. 4 is the stop 14 which, in the exemplary embodiment, is likewise connected in one piece to the housing 10 of the electrical device 1. The stop 14 has a second securing face 15 which, for example, results from a further recess, not specifically designated, in the region of the stop 14.

The fixing means 12, the stop 14, the holder 16 and the card 20 interact in the installed state of the card 20 in the electrical device, that is to say when the card 20 is fixed in the electrical device 1, in such a way that the card 20 rests firstly on the holder 16 and that a first side 21 of the card 20 interacts with the free end of the fixing means 12 and in particular with the first securing face 13 in such a way that the first side 21 of the card 20 is prevented by the securing face 13 from becoming detached from the holder 16, and that, secondly, a second side 22 of the card 20 interacts with the holder 14 and in particular with the second securing face 15 in such a way that the second side 22 of the card 20 is also prevented by the second securing face 15 from becoming detached from the holder 16.

Both during the installation of the card 20 in the electrical device 1 and during the removal of the card 20 from the electrical device 1, the fixing means 12 have to be deflected.

This is done, for example, in that in order to fix the card 20 in the electrical device 1, the first side 21 of the card 20 is guided into the recess at the free end of the fixing means 12, so that the card 20 is guided by the contact with the first securing face 13, and in that the card 20 is then displaced, counter to the restoring force of the fixing means 12, in such a way that the second side 22 of the card 20 can be laid on the support 16 and, as the result of renewed displacement of the card 20—substantially in the opposite direction—the second side 22 of the card 20 can be secured by the second securing face 15 against becoming detached from the holder 16.

One further possible way of fixing the card 20 to the housing 10 of the electrical device 1 is for the second side 22 of the card 20 to be brought into contact with the second securing face 15 and at least partly into contact with the holder 16, but the card 20 being oblique and resting with its first side 21 approximately in the central region of the second leg of the fixing means 12. As a result of pressure on the card 20 in the direction of the holder 16, the first side 21 of the card 20 effects a deflection of the fixing means 12, so that when the card 20 is resting completely on the holder 16, the fixing means 12 move back at least partly from their deflected position and, in the process, the first side 21 of the card 20 is prevented by the first securing face 13 from becoming detached from the holder 16.

In order to detach the card 20 from the electrical device 1, the invention provides in particular for the card 20 to be displaced parallel to the holder 16 on its second side 22 to such an extent that the second securing face 15 releases the second side 22, and therefore detachment of the card 20 from the housing 10 of the electrical device 1 is made possible. During this displacement of the card 20 parallel to the holder 16, the fixing means 12 are in turn deflected.

With a card 20 fixed to the housing 10 of the electrical device, the fixing means 12 can also be permanently in a deflected position, so that with the card 20 inserted into the housing 10, a restoring force starting from the fixing means 12 is exerted constantly onto the card 20, and is absorbed by the stop 14.

In order to detach the card 20 from the housing 10 of the electrical device 1, a recess 18 in the region of the stop 14, which is also designated a detachment means 18, is particularly suitable. Through the recess 18, a user can conveniently, for example by means of one of his fingernails, displace the card 20 counter to the restoring force of the fixing means 12 and parallel to the holder 16 in such a way that the second side 22 of the card 20 is released by the second securing face 15 and can therefore be detached.

According to the invention, the holder 16 of the card 20 can be connected in one piece to the housing 10 or else provided in the form of a card reader for supporting the card.

According to the invention, an identification card, in particular, is provided as the card 20. According to the invention, however, for example memory cards or combined identification and memory cards can also be used. In particular, SIM cards (subscriber identification module) can also be used according to the invention as identification cards.

1. An electrical device (1) comprising a housing (10) and comprising fixing means (12) for the detachable fixing of a card (20) to the housing (10), characterized in that the fixing means (12) are provided in a bracket shape in such a way that elastic deflection of the fixing means (12) from an inactive position is possible, the fixing means (12) being deflected at least temporarily out of the inactive position in order to fix the card (20) to the housing (10).

2. The electrical device (1) as claimed in claim 1, characterized in that the electrical device (1) comprises a stop (14) for fixing the card (20), the stop (14) interacting with the fixing means (12) and the card in such a way that during the fixing of the card by the fixing means (12), the action of a force absorbed by the stop (14) is exerted at least temporarily on the card (20).

3. The electrical device (1) as claimed in claim 1 or 2, characterized in that the fixing means (12) and the stop (14) are connected in one piece at least to part of the housing (10).

4. The electrical device (1) as claimed in one of the preceding claims, characterized in that the fixing means (12) comprises a first securing face (13) and in that the stop (14) comprises a second securing face (15), the securing faces (14, 15) fixing the card (20) to the housing (10).

5. The electrical device (1) as claimed in one of the preceding claims, characterized in that the fixing means (12) are deflected from the inactive position when the card (20) is fixed to the housing (10).

6. The electrical device (1) as claimed in one of the preceding claims, characterized in that during the detachment of the fixing of the card (20), the fixing means (12) are deflected at least temporarily from their position with the card (20) fixed to the housing (10).

7. The electrical device (1) as claimed in claim 6, characterized in that in the region of the stop (14), means for detaching (18) the card (20) are provided, the means for detaching (18) the card (20) being suitable, as a result of displacement of the card (20), to effect a deflection of the fixing means (12) and cancelation of the fixing of the card (20) with respect to the second securing face (15).

8. The electrical device (1) as claimed in claim 7, characterized in that the detachment means (18) are provided in the form of a recess in the region of the stop (14).

9. The electrical device (1) as claimed in one of the preceding claims, characterized in that the card (20) is an identification card, in particular a SIM card (subscriber identification module).
